(19) United States
(12) Patent Application Publication
(10) Pub. No.: US 2026/0261073 A1
(43) Pub. Date: Sep. 3, 2026

(54) CONNECTOR DEVICE

(71) Applicants: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(72) Inventors: Akira MIYAJO, Yokkaichi-Shi, Mie (JP); Makoto MASHITA, Yokkaichi-Shi, Mie (JP); Takuya IWAMOTO, Yokkaichi-Shi, Mie (JP); Masakatsu MORIGUCHI, Yokkaichi-Shi, Mie (JP)

(73) Assignees: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(21) Appl. No.: 18/879,526

(22) PCT Filed: Jun. 9, 2023
(86) PCT No.: PCT/JP2023/021575

§ 371 Date: Dec. 27, 2024

(30) Foreign Application Priority Data
Jun. 29, 2022 (JP) 2022-104763

(51) Int. Cl. H01R 13/533; H01R 12/72

(52) U.S. Cl. CPC H01R 13/533; H01R 12/722

(57) ABSTRACT

A connector device includes a circuit board provided with a main ground circuit and a connector mounted on the circuit board. The connector includes a sub-board, an IC mounted on the sub-board, and heat transfer portions (a heat dissipation sheet, a metal plate, an outer conductor, sub-ground circuits, a conductive member, and a mounting connector portion) that transfer heat of the IC to the main ground circuit. With this configuration, since the heat of the IC can be transferred to the main ground circuit via the heat transfer portions, the heat of the IC can be readily released.

### CROSS-REFERENCE TO RELATED APPLICATIONS

This application is the U.S. national stage of PCT/JP2023/021575 filed on Jun. 9, 2023, which claims priority of Japanese Patent Application No. JP 2022-104763 filed on Jun. 29, 2022, the contents of which are incorporated herein.

### TECHNICAL FIELD

The present disclosure relates to a connector device.

### BACKGROUND

JP 2021-061188A discloses a board connector to be mounted on a board.

When an IC (Integrated Circuit) is incorporated into this type of connector, heat generated by the IC will be an issue.

The present disclosure aims to provide a technique by which heat of an IC incorporated into a connector is readily released.

### SUMMARY

A connector device according to the present disclosure includes: a circuit board provided with a main ground circuit; and a connector mounted on the circuit board, in which the connector includes a sub-board, an IC mounted on the sub-board, and a heat transfer portion that transfers heat of the IC to the main ground circuit.

### Advantageous Effects

According to the connector device of the present disclosure, heat of an IC incorporated into a connector can be readily released.

### BRIEF DESCRIPTION OF DRAWINGS

FIG. 1 is a plan view of a connector device (excluding a cover member) of Embodiment 1.

FIG. 2 is a cross-sectional view taken along line A-A in FIG. 1.

FIG. 3 is a cross-sectional view taken along line B-B in FIG. 1.

FIG. 4 is a diagram schematically illustrating a path for transferring heat of an IC to a shield layer in Embodiment 1.

FIG. 5 is a diagram schematically illustrating a path for transferring heat of the IC to a main ground circuit in Embodiment 1.

FIG. 6 is a diagram corresponding to FIG. 3 of Embodiment 2.

FIG. 7 is an exploded perspective view of a circuit board, a cover member, and an attachment member in Embodiment 2.

FIG. 8 is a diagram schematically illustrating a path for transferring heat of an IC to a shield layer, and a path for transferring heat of the IC to a main ground circuit in Embodiment 2.

FIG. 9 is a diagram corresponding to FIG. 3 of Embodiment 3.

FIG. 10 is an exploded perspective view of a circuit board and a mounting cover member in Embodiment 3.

FIG. 11 is a diagram schematically illustrating a path for transferring heat of an IC to a shield layer, and a path for transferring heat of the IC to a main ground circuit in Embodiment 3.

### DETAILED DESCRIPTION OF PREFERRED EMBODIMENTS

First, embodiments of the present disclosure will be listed and described below.

In a first aspect, a connector device according to the present disclosure includes: a circuit board provided with a main ground circuit; and a connector mounted on the circuit board, in which the connector includes a sub-board, an IC mounted on the sub-board, and a heat transfer portion that transfers heat of the IC to the main ground circuit.

With this configuration, since the heat of the IC can be transferred to the main ground circuit via the heat transfer portion, the heat of the IC can be readily released.

In a second aspect according to the first aspect, the sub-board and the IC may be disposed on one side of the circuit board in a board thickness direction. The connector may have a conductive cover member disposed to cover the sub-board and the IC from the one side of the circuit board in the board thickness direction. The heat transfer portion may have a heat transfer portion for a cover that transfers heat of the IC to the cover member, and may transfer the heat of the IC to the main ground circuit via the heat transfer portion for a cover and the cover member.

With this configuration, the heat of the IC can be released to the main ground circuit using the cover member.

In a third aspect according to the second aspect, the connector may have a conductive attachment member mounted on the main ground circuit. The cover member may be detachably attached to the attachment member.

With this configuration, the heat of the IC can be released to the main ground circuit using the heat transfer portion for a cover, the cover member, and the attachment member. Further, the cover member is detachable from the circuit board.

In a fourth aspect according to the first aspect, the circuit board and the sub-board may be disposed such that their surfaces face each other. The sub-board may be provided with a sub-ground circuit disposed to face the main ground circuit provided on the circuit board. The IC may be connected to the sub-ground circuit. A conductive member may be provided between the sub-ground circuit and the main ground circuit. The conductive member may be capable of electrical conduction between the sub-ground circuit and the main ground circuit.

With this configuration, since the conductive member is capable of electrical conduction between the sub-ground circuit and the main ground circuit that face each other, it is possible to shorten a heat transfer path for transferring the heat of the IC to the main ground circuit. It is sufficient that the connector device according to (4) above is configured such that at least a portion of the main ground circuit and at least a portion of the sub-ground circuit face each other, and the conductive member is disposed between their opposing portions. That is, the connector device according to (4) above may be configured such that the entire main ground circuit faces the entire sub-ground circuit, or such that the entire main ground circuit faces only a portion of the sub-ground circuit, or such that only a portion of the main ground circuit faces the entire sub-ground circuit, or such that only a portion of the main ground circuit faces only a portion of the sub-ground circuit.

In a fifth aspect according to the fourth aspect, the connector may have a mounting portion that is mounted on the circuit board and holds the sub-board. The conductive member may bias the circuit board and the sub-board such that the circuit board and the sub-board are separated from each other in a direction in which their surfaces face each other.

With this configuration, since the sub-board is held by the mounting portion so as not to separate from the circuit board and the conductive member is pressed against the main ground circuit of the circuit board and the sub-ground circuit of the sub-board, stable contact between the conductive member and the sub-ground circuit and stable contact between the conductive member and the main ground circuit are readily maintained.

In a sixth aspect according to the first aspect, the connector may have a conductive mounting cover member that covers the sub-board and the IC and is mounted on the main ground circuit. The heat transfer portion may have a heat transfer portion for a mounting cover that transfers heat of the IC to the mounting cover member, and may transfer the heat of the IC to the main ground circuit by the heat transfer portion for a mounting cover and the mounting cover member.

With this configuration, the heat of the IC can be released to the main ground circuit using the mounting cover member.

In a seventh aspect according to the first aspect, the connector may have an inner conductor and an outer conductor covering an outer periphery of the inner conductor. The outer conductor may be provided on the main ground circuit. The heat transfer portion may have a heat transfer portion for an outer conductor that transfers heat of the IC to the outer conductor, and may transfer the heat of the IC to the main ground circuit by the heat transfer portion for an outer conductor and the outer conductor.

With this configuration, the heat of the IC can be released to the main ground circuit using the outer conductor.

In an eighth aspect according to any one of the first through the seventh aspects, the connector may have an outer conductor capable of electrical conduction with a shield layer of a shielded wire, and the heat transfer portion may further transfer the heat of the IC to the shield layer.

With this configuration, the heat of the IC can be released not only to the main ground circuit but also to the shield layer of the shielded wire.

In a ninth aspect according to the eighth aspect, the heat transfer portion may have a heat transfer portion for an outer conductor that transfers heat of the IC to the outer conductor, and may further transfer the heat of the IC to the shield layer via the heat transfer portion for an outer conductor and the outer conductor.

With this configuration, the heat of the IC can be released to the shield layer using the outer conductor.

In a tenth aspect according to the ninth aspect, the heat transfer portion for an outer conductor may include a metal plate.

With this configuration, it is possible to improve the heat transfer efficiency of the heat transfer portion for an outer conductor.

In an eleventh aspect according to the tenth aspect, the heat transfer portion for an outer conductor may have a first contact portion that is in contact with a surface of the IC on a side opposite to the sub-board side, a second contact portion that is in contact with the outer conductor at a height position different from a position of contact with the IC, and a step portion that connects the first contact portion and the second contact portion in a step shape.

With this configuration, portions of the IC and the outer conductor that are located at different height positions can be connected by the heat transfer portion for an outer conductor.

In a twelfth aspect according to the eighth aspect, the heat transfer portion for an outer conductor may be constituted by the sub-ground circuit provided on the sub-board.

With this configuration, the size reduction of the heat transfer portion for an outer conductor can be easily achieved.

In a thirteenth aspect according to the twelfth aspect, the sub-ground circuit may have a sub-extension circuit, the outer conductor may have an overhang portion protruding in a direction in which the sub-extension circuit that is to come into contact with the overhang portion extends, and the overhang portion may be configured to be in contact with the sub-extension circuit.

With this configuration, the contact area between the outer conductor and the sub-ground circuit can be easily increased, thus improving the heat transfer efficiency.

In a fourteenth aspect according to the thirteenth aspect, the outer conductor may have a restricting portion positioned on a side of the sub-board opposite to the overhang portion.

With this configuration, because the restricting portion can restrict separation of the sub-board from the overhang portion, the overhang portion and the sub-extension circuit can be readily kept in a contact state.

Specific examples of the present disclosure will be described below with reference to the drawings. Note that the present disclosure is not limited to these examples, and is indicated by the claims, and is intended to include all modifications within the meaning and scope equivalent to the claims.

### Embodiment 1

### Configuration of Connector Device 1

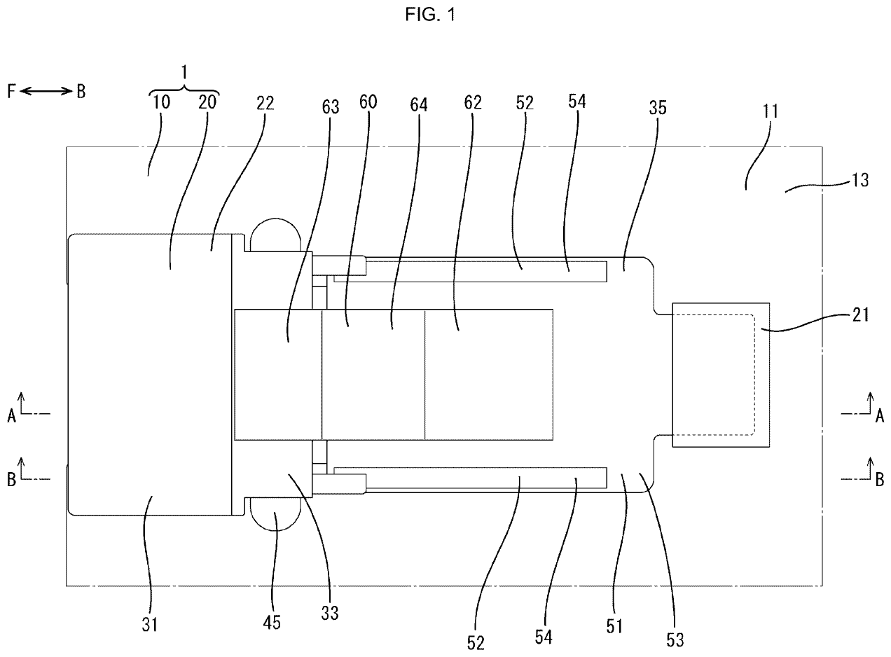

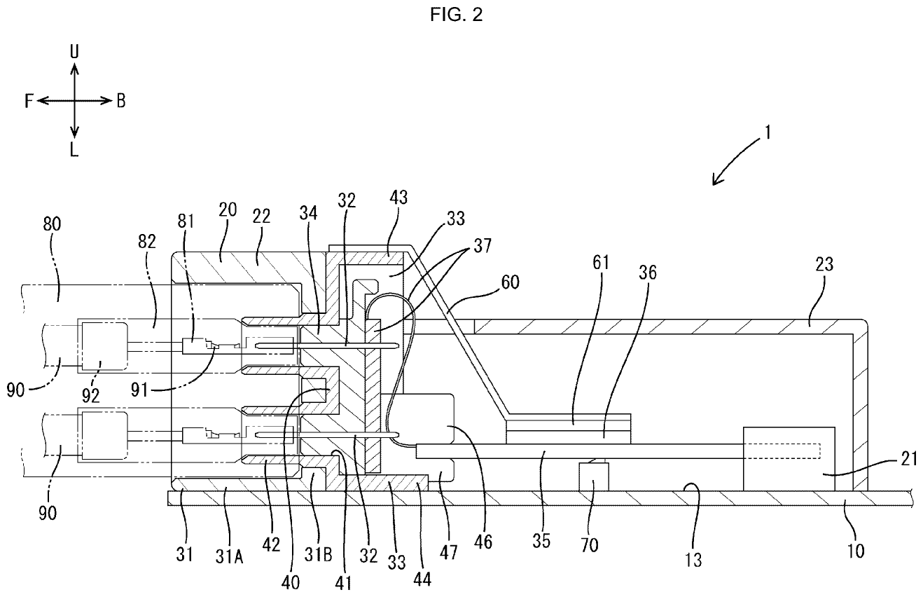

FIG. 1 discloses a connector device 1 according to Embodiment 1. The connector device 1 is mounted in a vehicle, for example. FIG. 1 shows the connector device 1 from which a cover member 23 (see FIG. 2), which will be described later, has been removed. The connector device 1 includes a circuit board 10 and a connector 20 mounted on the circuit board 10. As shown in FIG. 2, the connector 20 fits to a counterpart connector 80. In this embodiment, the side of the circuit board 10 on which the connector 20 is mounted is defined as an upper side. The side of the connector 20 where the counterpart connector 80 fits thereto is defined as a front side. A direction orthogonal to an up-down direction and a front-rear direction is defined as a width direction. In the drawings, the directions of up, down, front, and rear are respectively indicated by “U”, “L”, “F”, and “B”.

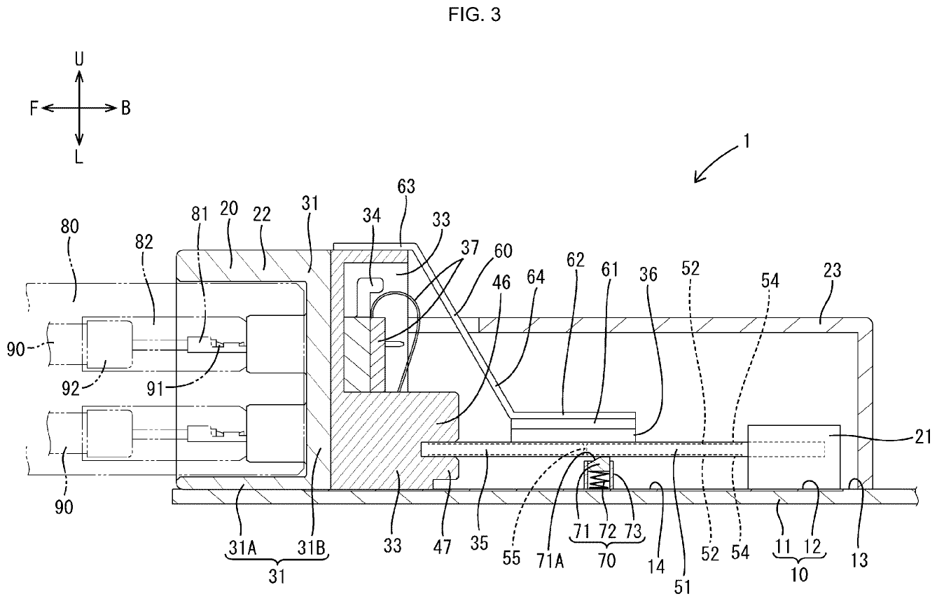

The circuit board 10 is plate-shaped. The thickness direction of the circuit board 10 is the up-down direction, and is orthogonal to the board surface of the circuit board 10. As shown in FIG. 3, the circuit board 10 has a board body 11 and a main ground circuit 12. The board body 11 is plate-shaped. The board body 11 has insulating properties and is made of, for example, resin. The board body 11 has a mounting surface 13. The mounting surface 13 is formed on an upper surface of the board body 11.

As shown in FIG. 3, the main ground circuit 12 is provided on the circuit board 10 (more specifically, on the mounting surface 13). The main ground circuit 12 is exposed on the mounting surface 13 of the circuit board 10. The main ground circuit 12 has an extension circuit 14 extending in the front-rear direction along the mounting surface 13. A plurality of the extension circuits 14 are provided at intervals in the width direction.

As shown in FIG. 2, the connector 20 is a board connector mounted on the circuit board 10. The connector 20 has a mounting connector portion 21 mounted on the circuit board 10, a relay connector portion 22 connected to the mounting connector portion 21, and a cover member 23.

The mounting connector portion 21 corresponds to an example of the “mounting portion”. As shown in FIG. 2, the mounting connector portion 21 is configured as a card edge connector, for example. The relay connector portion 22 is detachably connected to the mounting connector portion 21. An opening is formed in a front surface of the mounting connector portion 21. By inserting the relay connector portion 22 into the opening from the front, the relay connector portion 22 is connected to the mounting connector portion 21.

As shown in FIG. 2, the relay connector portion 22 is detachably connected to the mounting connector portion 21. The relay connector portion 22 is connected to the mounting connector portion 21 and the counterpart connector 80. The relay connector portion 22 functions as an adapter. A plurality of types of relay connector portions 22 are prepared in advance according to, for example, the number of devices mounted in a vehicle and communication specifications (e.g., communication speed or the like). By connecting the relay connector portion 22, which corresponds to the specifications of the vehicle in which the connector device 1 is to be mounted, to the mounting connector portion 21, the connector device 1 can be used for multiple types of vehicles.

As shown in FIG. 2, the relay connector portion 22 has a fitting member 31, an inner conductor 32, an outer conductor 33, a dielectric 34, a sub-board 35, an IC 36, and relay portions 37.

As shown in FIG. 2, the fitting member 31 fits to a counterpart connector 80. The fitting member 31 has insulating properties and is made of, for example, resin. The fitting member 31 has a rectangular tubular hood portion 31A and a rear wall portion 31B covering a rear surface of the hood portion 31A.

As shown in FIG. 2, the inner conductor 32 extends in the front-rear direction. A plurality of the inner conductors 32 are provided spaced apart from each other in a direction orthogonal to the front-rear direction. A front end portion of each inner conductor 32 protrudes into the hood portion 31A, and a rear end portion of the inner conductor 32 protrudes rearward of the rear wall portion 31B. The inner conductor 32 is electrically continuous with a core wire 91 of a shielded wire 90 in a state in which the connector 20 and the counterpart connector 80 are fitted to each other. Specifically, the inner conductor 32 is electrically connected to a counterpart inner conductor 81 of the counterpart connector 80. The core wire 91 is electrically connected to the counterpart inner conductor 81. That is, the inner conductor 32 is electrically continuous with the core wire 91 via the counterpart inner conductor 81. The inner conductor 32 is electrically connected to a conductive path of the sub-board 35 via the relay portions 37.

As shown in FIG. 2, the outer conductor 33 covers an outer periphery of the inner conductor 32. The outer conductor 33 has a wall portion 40 having a thickness in the front-rear direction. The wall portion 40 has an insertion hole 41 for allowing insertion of the inner conductor 32. The outer conductor 33 has a tubular portion 42 protruding forward from an outer peripheral portion of the insertion hole 41 in a tubular shape. The tubular portion 42 extends through the rear wall portion 31B of the fitting member 31 and protrudes into the hood portion 31A. The outer conductor 33 is electrically continuous with the shield layer 92 of the shielded wire 90 in a state in which the connector 20 and the counterpart connector 80 are fitted to each other. Specifically, as a result of the counterpart outer conductor 82 of the counterpart connector 80 being fitted into the tubular portion 42, the outer conductor 33 is electrically connected to the counterpart outer conductor 82. The shield layer 92 is electrically connected to the counterpart outer conductor 82. That is, the outer conductor 33 is electrically continuous with the shield layer 92 via the counterpart outer conductor 82.

As shown in FIG. 2, the outer conductor 33 has an upper wall portion 43 protruding rearward from the upper end side of the wall portion 40. The outer conductor 33 has a bottom wall portion 44 protruding rearward from the lower end side of the wall portion 40.

As shown in FIG. 1, the outer conductor 33 has a fixing portion 45 protruding outward in the width direction. The fixing portion 45 is fixed to the circuit board 10 using a screw or the like. The outer conductor 33 is placed on the main ground circuit 12 and is electrically connected to the main ground circuit 12. The outer conductor 33 is fixed to the circuit board 10 by the fixing portion 45, thus more stabilizing the contact state between the outer conductor 33 and the main ground circuit 12.

As shown in FIG. 3, the outer conductor 33 has an overhang portion 46 and a restricting portion 47 that protrude rearward, at positions rearward of the wall portion 40. The overhang portion 46 and the restricting portion 47 are disposed spaced apart from each other in the up-down direction. The sub-board 35 is disposed in the gap between the overhang portion 46 and the restricting portion 47. The sub-board 35 is in contact with the overhang portion 46 and the restricting portion 47 and is sandwiched therebetween from above and below. The overhang portion 46 is disposed at a position above the restricting portion 47. The overhang portion 46 and the restricting portion 47 are respectively disposed on both sides of the outer conductor 33 in the width direction. The sub-board 35 is disposed in the gap between the overhang portion 46 and the restricting portion 47 on both sides of the outer conductor 33 in the width direction.

As shown in FIG. 2, the dielectric 34 is disposed between the inner conductor 32 and the outer conductor 33.

The sub-board 35 is plate-shaped. The thickness direction of the sub-board 35 is the up-down direction, is orthogonal to the board surface of the sub-board 35, and is an arrangement direction of the circuit board 10 and the sub-board 35. As shown in FIG. 2, the sub-board 35 is a board built in the connector 20. The sub-board 35 is detachably connected to the mounting connector portion 21. The sub-board 35 is capable of communicating with the circuit board 10 via the mounting connector portion 21. The sub-board 35 is disposed at a position above the circuit board 10. The sub-board 35 is disposed such that board surfaces of the sub-board 35 and the circuit board 10 face each other in the up-down direction. A lower surface of the sub-board 35 faces an upper surface of the circuit board 10. The sub-board 35 has a sub-board body 51 and sub-ground circuits 52.

As shown in FIG. 3, the sub-board body 51 is plate-shaped. The sub-board body 51 has insulating properties and is made of, for example, resin. As shown in FIG. 1, the sub-board body 51 has a sub-mounting surface 53. The sub-mounting surface 53 is formed on an upper surface of the sub-board body 51.

As shown in FIGS. 1 and 3, the sub-ground circuits 52 are provided on the sub-board 35 (more specifically, the sub-mounting surface 53). An IC 36 (more specifically, a lead wire of the IC 36) is electrically connected to the sub-ground circuits 52. The sub-ground circuits 52 are exposed on the sub-mounting surface 53 of the sub-board 35. Each sub-ground circuit 52 has a sub-extension circuit 54 extending in the front-rear direction along the sub-mounting surface 53. A plurality of the sub-extension circuits 54 are provided at intervals in the width direction. The sub-extension circuits 54 are provided on both the upper and lower surfaces of the sub-board 35. The sub-extension circuits 54 on both the upper and lower surfaces are electrically connected through a via 55 that extends through the sub-board body 51 in the thickness direction. In a state in which the sub-board 35 is disposed between the overhang portion 46 and the restricting portion 47 of the outer conductor 33, the sub-extension circuits 54 on the upper surface are in contact (more specifically, surface contact) with the lower surface of the overhang portion 46, and the sub-extension circuits 54 on the lower surface are in contact (more specifically, surface contact) with the upper surface of the restricting portion 47. That is, the IC 36 is electrically connected to the outer conductor 33 via the sub-ground circuits 52.

The IC 36 is mounted on the sub-mounting surface 53 (the upper surface) of the sub-board 35.

As shown in FIG. 2, the relay connector portion 22 has a metal plate 60 and a heat dissipation sheet 61. The metal plate 60 is joined to the upper surface of the upper wall portion 43 of the outer conductor 33, and is joined to the upper surface of the IC 36 via the heat dissipation sheet 61. The metal plate 60 and the heat dissipation sheet 61 form a first contact portion 62 that is in contact (more specifically, surface contact) with the upper surface of the IC 36, a second contact portion 63 that is in contact (more specifically, surface contact) with the outer conductor 33 at a height position different from the position of the upper surface of the IC 36, and a step portion 64 that connects the first contact portion 62 and the second contact portion 63 in a step shape.

As shown in FIG. 3, the relay connector portion 22 has a conductive member 70. The above-described main ground circuit 12 and sub-ground circuits 52 are disposed facing each other vertically. The conductive member 70 is disposed between the main ground circuit 12 and the sub-ground circuits 52 that are disposed facing each other, and electrically connected to the main ground circuit 12 and the sub-ground circuits 52. The conductive member 70 includes a contact conductive portion 71 that is in contact with the sub-ground circuits 52, a biasing member 72 disposed between the contact conductive portion 71 and the main ground circuit 12, and a guide portion 73 that guides the contact conductive portion 71 in the up-down direction. The contact conductive portion 71 has an inclined surface 71A inclined downward toward the front end. When the inclined surface 71A is pressed by the sub-board 35 from the front, the contact conductive portion 71 moves downward. The biasing member 72 is, for example, a spring member, and biases the contact conductive portion 71 in a direction away from the main ground circuit 12. On the other hand, the sub-board 35 is held by the mounting connector portion 21, and movement of the sub-board 35 in a direction away from the circuit board 10 (more specifically, upward) is restricted. Thus, the conductive member 70 is pressed against the main ground circuit 12 and the sub-ground circuits 52.

As shown in FIG. 2, the cover member 23 covers the sub-board 35 and the IC 36 from above. The cover member 23 is fixed to the circuit board 10 using a screw or the like.

### Functional Effects of Connector Device 1

The connector device 1 can release heat of the IC 36 to the shield layer 92 of the shielded wire 90 as follows.

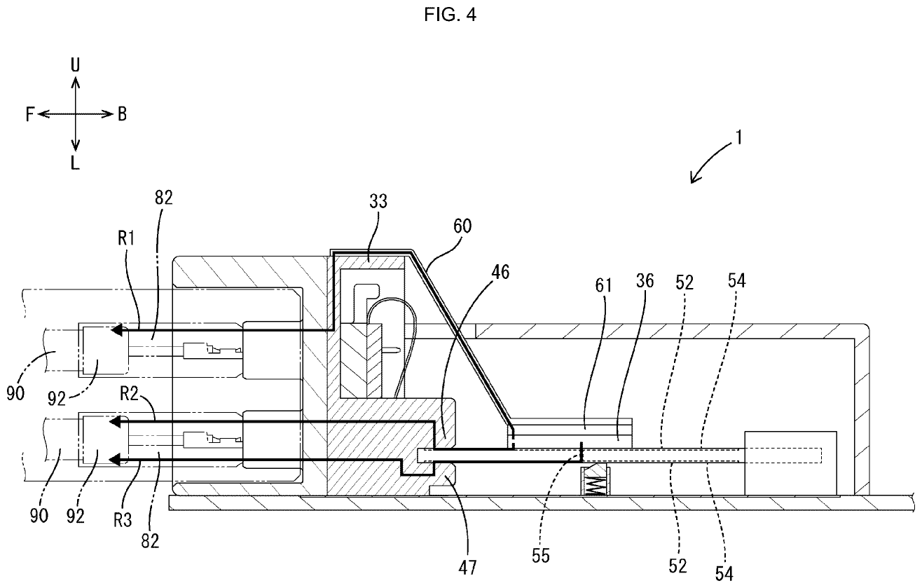

The heat of the IC 36 is transferred to the outer conductor 33 by the heat dissipation sheet 61 and the metal plate 60. As described above, the outer conductor 33 is electrically continuous with the shield layer 92. Thus, as indicated by a path R1 shown in FIG. 4, the connector device 1 can release heat of the IC 36 to the shield layer 92 via the heat dissipation sheet 61, the metal plate 60, and the outer conductor 33.

Furthermore, the connector device 1 can release the heat of the IC 36 to the shield layer 92 using the outer conductor 33.

Further, through the path R1, heat of the IC 36 is transferred to the outer conductor 33 via the metal plate 60, and thus the heat transfer efficiency can be improved.

Through the path R1, the heat dissipation sheet 61 is in surface contact with the IC 36, and thus the efficiency of heat transfer from the IC 36 to the heat dissipation sheet 61 can be improved. The metal plate 60 is in surface contact with the heat dissipation sheet 61, and thus the efficiency of heat transfer from the heat dissipation sheet 61 to the metal plate 60 can be improved. The metal plate 60 is in surface contact with the outer conductor 33, and thus the efficiency of heat transfer from the metal plate 60 to the outer conductor 33 can be improved. That is, through the path R1, the efficiency of heat transfer from the IC 36 to the outer conductor 33 can be improved.

Furthermore, the metal plate 60 and the heat dissipation sheet 61 form the first contact portion 62 that is in contact (more specifically, surface contact) with the upper surface of the IC 36, the second contact portion 63 that is in contact (more specifically, surface contact) with the outer conductor 33 at a height position different from the position of the upper surface of the IC 36, and the step portion 64 that connects the first contact portion 62 and the second contact portion 63 in a step shape. Therefore, surfaces of the IC 36 and the outer conductor 33 that are located at different height positions can be connected by the metal plate 60 and the heat dissipation sheet 61. Note that a “height position” refers to a position in the up-down direction (a direction orthogonal to the sub-mounting surface 53) based on the sub-mounting surface 53 of the sub-board 35.

Also, heat of the IC 36 is transferred to the outer conductor 33 by the sub-extension circuits 54 on both the upper and lower surfaces of the sub-board 35. As described above, the outer conductor 33 is electrically continuous with the shield layer 92. Thus, as indicated by a path R2 shown in FIG. 4, the connector device 1 can release heat of the IC 36 to the shield layer 92 via the sub-extension circuits 54 on the upper surface and the outer conductor 33. Also, as indicated by a path R3 shown in FIG. 4, the connector device 1 can release heat of the IC 36 to the shield layer 92 through the via 55, the sub-extension circuits 54 on the lower surface, and the outer conductor 33.

Through the paths R2 and R3, the connector device 1 can also release the heat of the IC 36 to the shield layer 92 using the outer conductor 33.

Further, through the paths R2 and R3, the connector device 1 can ensure a heat transfer path from the IC 36 to the outer conductor 33 while achieving a size reduction of the connector device 1.

The outer conductor 33 has the overhang portion 46 protruding rearward. The lower surface of the overhang portion 46 is in contact (more specifically, surface contact) with the sub-extension circuits 54 extending in the front-rear direction through the path R2. Thus, in the connector device 1, the contact area between the outer conductor 33 and the sub-ground circuits 52 can be easily increased, thus improving the heat transfer efficiency.

The outer conductor 33 has the restricting portion 47 positioned on the side of the sub-board 35 opposite to the overhang portion 46. With this configuration, because the restricting portion 47 can restrict separation of the sub-board 35 from the overhang portion 46, the overhang portion 46 and the sub-extension circuits 54 can be readily kept in a contact state. Further, the restricting portion 47 also protrudes rearward, and the upper surface of the restricting portion 47 is in contact (more specifically, surface contact) with the sub-extension circuits 54 extending in the front-rear direction in the path R3. Thus, in the connector device 1, the contact area between the outer conductor 33 and the sub-ground circuits 52 can be easily increased on both surfaces of the sub-board 35, thus improving the heat transfer efficiency.

Also, the connector device 1 can release the heat of the IC 36 to the main ground circuit 12 as follows.

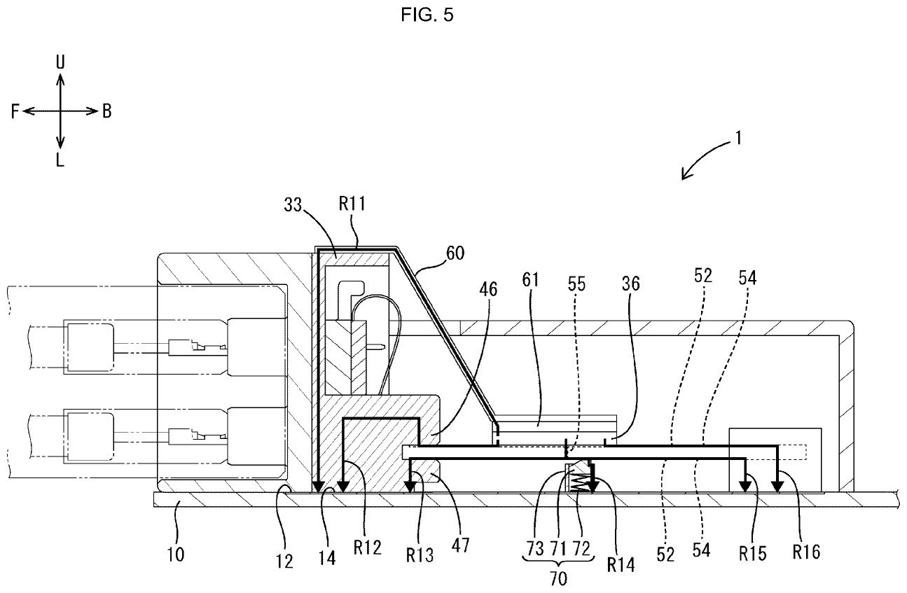

As described above in the description of the path R1, heat of the IC 36 is transferred to the outer conductor 33 by the heat dissipation sheet 61 and the metal plate 60. Also, the outer conductor 33 is electrically connected to the main ground circuit 12. Thus, as indicated by a path R11 shown in FIG. 5, the connector device 1 can release heat of the IC 36 to the main ground circuit 12 via the heat dissipation sheet 61, the metal plate 60, and the outer conductor 33.

Further, the connector device 1 can release the heat of the IC 36 to the main ground circuit 12 using the outer conductor 33.

As described above in the description of the paths R2 and R3, heat of the IC 36 is transferred to the outer conductor 33 by the sub-extension circuits 54 on both the upper and lower surfaces of the sub-board 35. Also, the outer conductor 33 is electrically connected to the main ground circuit 12. Thus, as indicated by a path R12 shown in FIG. 5, the connector device 1 can release heat of the IC 36 to the main ground circuit 12 via the sub-extension circuits 54 on the upper surface and the outer conductor 33. Also, as indicated by a path R13 shown in FIG. 5, the connector device 1 can release heat of the IC 36 to the main ground circuit 12 through the via 55, the sub-extension circuits 54 on the lower surface and the outer conductor 33. Through these paths R12 and R13, the connector device 1 can release the heat of the IC 36 to the main ground circuit 12 using the outer conductor 33.

Also, the sub-ground circuits 52 are electrically connected to the main ground circuit 12 via the conductive member 70. Thus, as indicated by a path R14 shown in FIG. 5, the connector device 1 can release heat of the IC 36 to the main ground circuit 12 via the sub-ground circuits 52 and the conductive member 70.

Further, since the conductive member 70 is capable of electrical conduction between the sub-ground circuits 52 and the main ground circuit 12 that face each other in the connector device 1, it is possible to shorten a heat transfer path for transferring the heat of the IC 36 to the main ground circuit 12.

In addition, the sub-board 35 is held by the mounting connector portion 21, and the conductive member 70 biases the circuit board 10 and the sub-board 35 such that the circuit board 10 and the sub-board 35 separate from each other in a direction in which their surfaces face each other. With this configuration, since the sub-board 35 is held by the mounting connector portion 21 so as not to separate from the circuit board 10 and the conductive member 70 is pressed against the main ground circuit 12 of the circuit board 10 and the sub-ground circuits 52 of the sub-board 35, stable contact between the conductive member 70 and the sub-ground circuits 52 and stable contact between the conductive member 70 and the main ground circuit 12 are readily maintained. Note that the “direction in which surfaces face each other” refers to a direction in which the main ground circuit 12 and the sub-ground circuits 52 face each other. Also, the “direction in which surfaces face each other” refers to a direction orthogonal to the direction in which the connector 20 and the counterpart connector 80 are fitted to each other.

As indicated by paths R15 and R16 shown in FIG. 5, the connector device 1 can release heat of the IC 36 to the main ground circuit 12 via the mounting connector portion 21.

### Embodiment 2

In Embodiment 2, an example in which a cover member is used to dissipate heat will be described. Note that the same constituent elements as those in Embodiment 1 are given the same reference numerals, and detailed description thereof will be omitted.

### Configuration of Connector Device 201

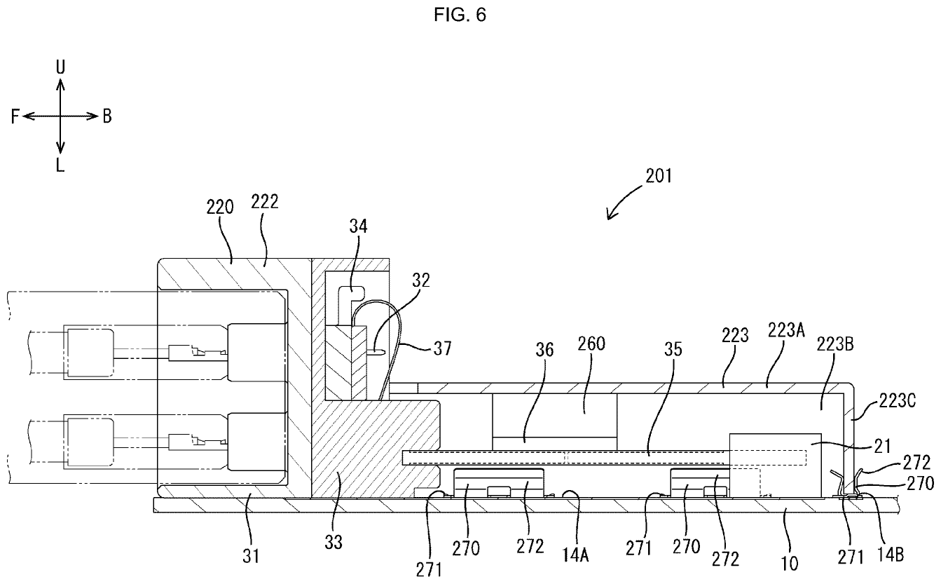

FIG. 6 discloses a connector device 201 according to Embodiment 2. The connector device 201 is mounted in a vehicle, for example. The connector device 201 includes a circuit board 10 and a connector 220 mounted on the circuit board 10.

As shown in FIG. 6, the connector 220 is a board connector mounted on the circuit board 10. The connector 220 has a mounting connector portion 21, a relay connector portion 222 connected to the mounting connector portion 21, a cover member 223, and attachment members 270.

As shown in FIG. 6, the relay connector portion 222 has a fitting member 31, an inner conductor 32, an outer conductor 33, a dielectric 34, a sub-board 35, an IC 36, and relay portions 37.

As shown in FIG. 6, the relay connector portion 222 has a heat dissipation sheet 260. The heat dissipation sheet 260 is placed on the upper surface of the IC 36.

The cover member 223 is conductive and is configured as, for example, a metal housing. As shown in FIG. 6, the cover member 223 covers the sub-board 35 and the IC 36. The cover member 223 is fixed to the circuit board 10 using a screw or the like. The cover member 223 has a top plate 223A, a pair of side plates 223B, and a rear plate 223C. The pair of side plates 223B are disposed at an interval in the width direction. Both end portions of the top plate 223A in the width direction are continuous with the upper end portions of the pair of side plates 223B. The rear plate 223C is continuous with rear end portions of the top plate 223A and the pair of side plates 223B. A lower surface and a front surface of the cover member 223 are open.

As shown in FIG. 6, the cover member 223 is disposed in a state in which the top plate 223A is in contact with the upper surface of the heat dissipation sheet 260. Also, the cover member 223 is disposed in a state in which the top plate 223A is in contact with the rear surface of the outer conductor 33. The cover member 223 is fixed to the circuit board 10 using the attachment members 270.

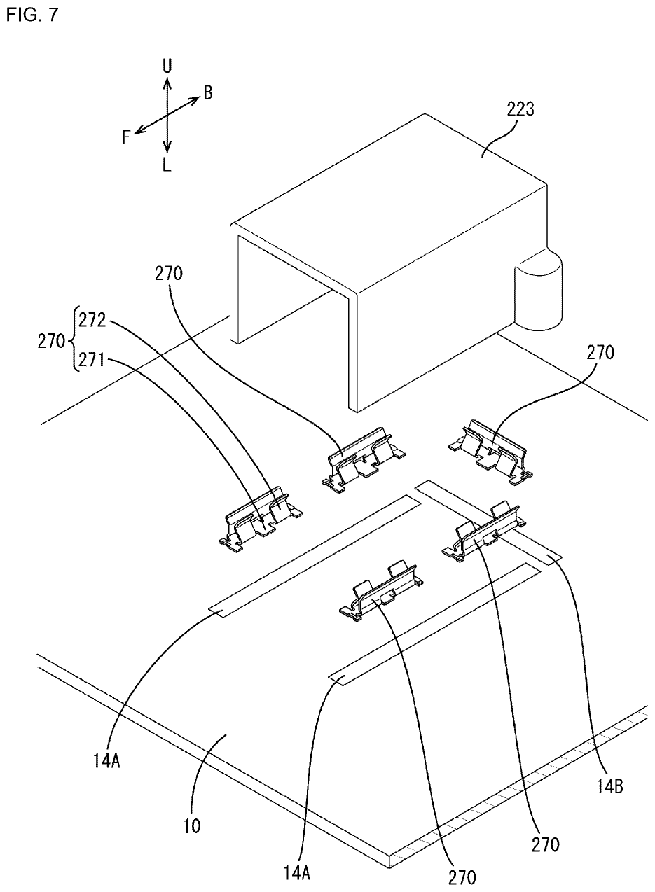

As shown in FIG. 7, the main ground circuit 12 has extension circuits 14A extending in the front-rear direction along the mounting surface 13, and an extension circuit 14B extending in the width direction. The extension circuits 14A and 14B are disposed in correspondence with the positions of the lower end portions of the cover member 223. A plurality of attachment members 270 are mounted on the extension circuits 14A and 14B.

The attachment members 270 are conductive and are made of, for example, metal. Each attachment member 270 includes a plate-shaped base portion 271 fixed onto the extension circuit 14A or 14B, and holding portions 272 that extend upward in a cantilever shape from both sides of the base portion 271 to sandwich the cover member 223 therebetween. The minimum distance between the holding portions 272 is smaller than the thickness of the pair of side plates 223B and smaller than the thickness of the rear plate 223C. The cover member 223 is attached to the attachment members 270 from above to press and expand the holding portions 272. The cover member 223 is detachable from the attachment members 270.

### Functional Effects of Connector Device 201

The connector device 201 can release heat of the IC 36 to a shield layer 92 of a shielded wire 90 as follows.

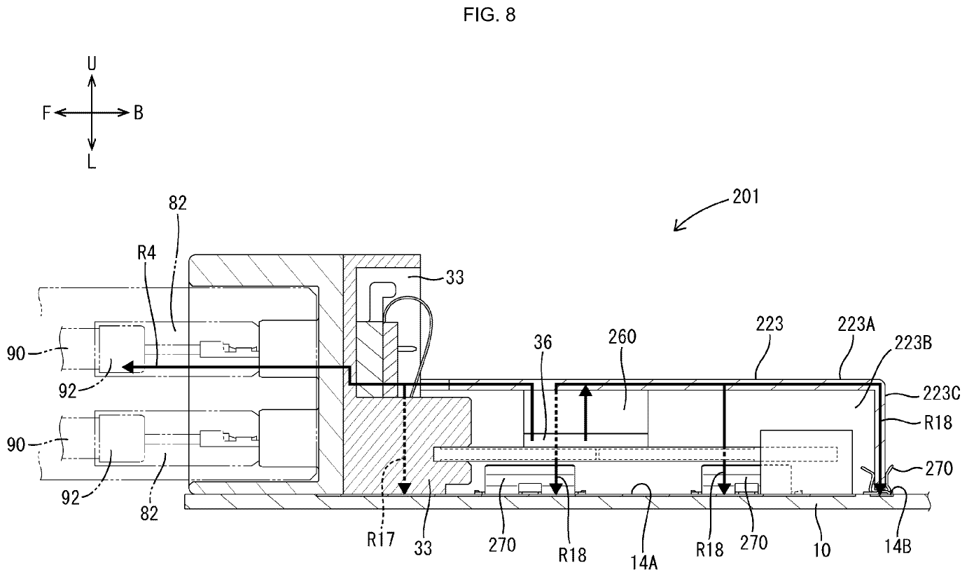

The heat of the IC 36 is transferred to the outer conductor 33 by the heat dissipation sheet 260 and the cover member 223. The outer conductor 33 is electrically continuous with the shield layer 92. Thus, as indicated by a path R4 shown in FIG. 8, the connector device 201 can release heat of the IC 36 to the shield layer 92 via the heat dissipation sheet 260, the cover member 223, and the outer conductor 33. That is, the connector device 201 can release the heat of the IC 36 to the shield layer 92 using the cover member 223.

Note that the connector device 201 can also release heat of the IC 36 to the shield layer 92 as indicated by the paths R2 and R3 shown in FIG. 4 in the same manner as in Embodiment 1.

Also, the connector device 201 can release the heat of the IC 36 to the main ground circuit 12 as follows.

As described above, heat of the IC 36 is transferred to the outer conductor 33 by the heat dissipation sheet 260 and the cover member 223. The outer conductor 33 is electrically connected to the main ground circuit 12. Thus, as indicated by a path R17 shown in FIG. 8, the connector device 201 can release heat of the IC 36 to the main ground circuit 12 via the heat dissipation sheet 260, the cover member 223, and the outer conductor 33. That is, the connector device 201 can release the heat of the IC 36 to the main ground circuit 12 using the cover member 223.

Further, the heat of the IC 36 is transferred to the attachment members 270 by the heat dissipation sheet 260 and the cover member 223, and transferred to the main ground circuit 12 via the attachment members 270. Thus, as indicated by a path R18 shown in FIG. 8, the connector device 201 can release heat of the IC 36 to the main ground circuit 12 via the heat dissipation sheet 260, the cover member 223, and the attachment members 270. That is, the connector device 201 can release the heat of the IC 36 to the main ground circuit 12 using the cover member 223. In addition, the cover member 223 is detachable from the circuit board 10.

Note that the connector device 201 can also release heat of the IC 36 to the main ground circuit 12 as indicated by the paths R12, R13, R15, and R16 shown in FIG. 5 in the same manner as in Embodiment 1.

### Embodiment 3

In Embodiment 3, an example in which a mounting cover member mounted on a circuit board is used to dissipate heat will be described. Note that the same constituent elements as those in Embodiment 1 are given the same reference numerals, and detailed description thereof will be omitted.

### Configuration of Connector Device 301

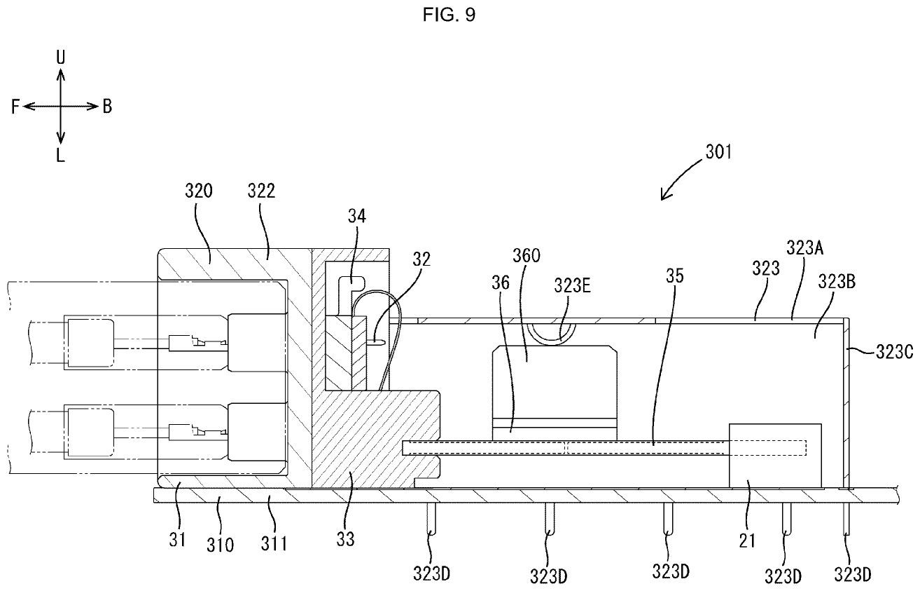

FIG. 9 discloses a connector device 301 according to Embodiment 3. The connector device 301 is mounted in a vehicle, for example. The connector device 301 includes a circuit board 310 and a connector 320 mounted on the circuit board 310.

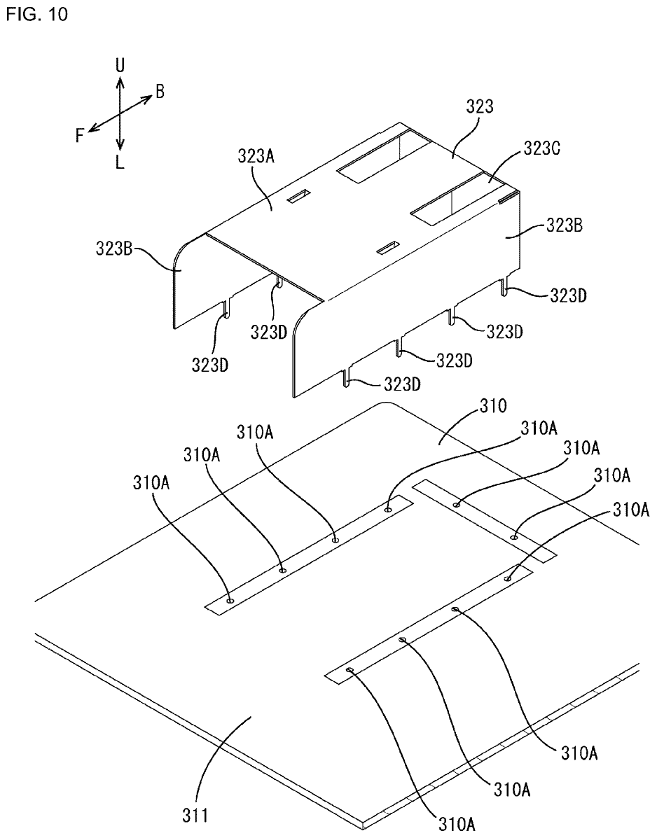

As shown in FIG. 10, the circuit board 310 has a board body 311 and a main ground circuit 12. Through holes 310A for mounting a later-described mounting cover member 323 are formed in the board body 311. The board body 311 is the same as the board body 11 of Embodiment 1 in other points.

As shown in FIG. 9, the connector 320 is a board connector mounted on the circuit board 310. The connector 320 has a mounting connector portion 21, a relay connector portion 322 connected to the mounting connector portion 21, and a mounting cover member 323.

As shown in FIG. 9, the relay connector portion 322 has a fitting member 31, an inner conductor 32, an outer conductor 33, a dielectric 34, a sub-board 35, an IC 36, and relay portions 37.

As shown in FIG. 9, the relay connector portion 322 has a heat dissipation fin 360. The heat dissipation fin 360 is placed on the upper surface of the IC 36.

The mounting cover member 323 is conductive and is made of, for example, metal. As shown in FIG. 9, the mounting cover member 323 covers the sub-board 35 and the IC 36, and is mounted on the main ground circuit 12 of the circuit board 310. The mounting cover member 323 has a top plate 323A, a pair of side plates 323B, a rear plate 323C, and a plurality of legs 323D. The pair of side plates 323B are disposed at an interval in the width direction. Both end portions of the top plate 323A in the width direction are continuous with the upper end portions of the pair of side plates 323B. The rear plate 323C is continuous with rear end portions of the top plate 323A and the pair of side plates 323B. The legs 323D protrude downward from the lower end portions of the pair of side plates 323B and the rear plate 323C. A lower surface and a front surface of the mounting cover member 323 are open.

As shown in FIG. 9, the mounting cover member 323 has a holding protrusion 323E. The holding protrusion 323E protrudes downward from the top plate 323A. The holding protrusion 323E is disposed in contact with the upper end portion of the heat dissipation fin 360. Also, the mounting cover member 323 is disposed in a state in which the top plate 323A is in contact with the rear surface of the outer conductor 33.

As shown in FIG. 10, the above-described through-holes 310A are located at positions corresponding to the legs 323D of the mounting cover member 323. Also, the through-holes 310A are electrically connected to the main ground circuit 12. The mounting cover member 323 is mounted on the circuit board 310 in a state in which the legs 323D are inserted into the through-holes 310A. As a result, the mounting cover member 323 is electrically connected to the main ground circuit 12.

### Functional Effects of Connector Device 301

The connector device 301 can release heat of the IC 36 to a shield layer 92 of a shielded wire 90 as follows.

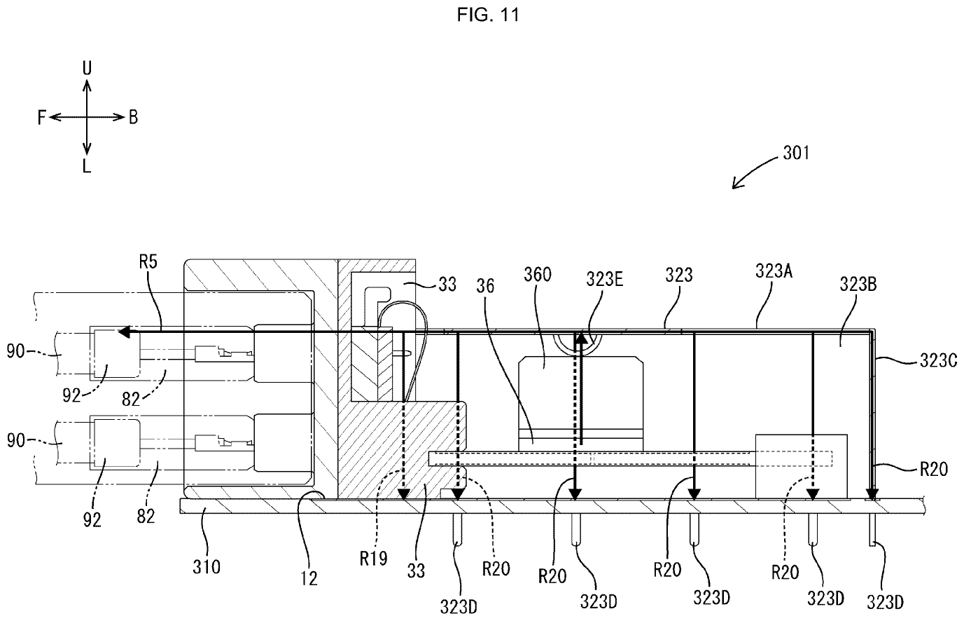

The heat of the IC 36 is transferred to the outer conductor 33 by the heat dissipation fin 360 and the mounting cover member 323. The outer conductor 33 is electrically continuous with the shield layer 92. Thus, as indicated by a path R5 shown in FIG. 11, the connector device 301 can release heat of the IC 36 to the shield layer 92 via the heat dissipation fin 360, the mounting cover member 323, and the outer conductor 33. That is, the connector device 301 can release the heat of the IC 36 to the shield layer 92 using the mounting cover member 323.

Note that the connector device 301 can also release heat of the IC 36 to the shield layer 92 as indicated by the paths R2 and R3 shown in FIG. 4 in the same manner as in Embodiment 1.

Also, the connector device 301 can release the heat of the IC 36 to the main ground circuit 12 as follows.

As described above, the heat of the IC 36 is transferred to the outer conductor 33 by the heat dissipation fin 360 and the mounting cover member 323. The outer conductor 33 is electrically connected to the main ground circuit 12. Thus, as indicated by a path R19 shown in FIG. 11, the connector device 301 can release heat of the IC 36 to the main ground circuit 12 via the heat dissipation fin 360, the mounting cover member 323, and the outer conductor 33. That is, the connector device 301 can release the heat of the IC 36 to the main ground circuit 12 using the mounting cover member 323.

The mounting cover member 323 is also mounted on the main ground circuit 12. Thus, as indicated by a path R20 shown in FIG. 11, the connector device 301 can release heat of the IC 36 to the main ground circuit 12 by the heat dissipation fin 360 and the mounting cover member 323. That is, the connector device 301 can also release the heat of the IC 36 to the main ground circuit 12 using the mounting cover member 323 through the path R20.

Note that the connector device 301 can also release heat of the IC 36 to the main ground circuit 12 as indicated by the paths R12, R13, R15, and R16 shown in FIG. 5 in the same manner as in Embodiment 1.

### Other Embodiments of the Present Disclosure

Embodiments disclosed herein are to be considered in all respects as illustrative and not restrictive.

Although the connector is configured such that the mounting connector portion and the relay connector portion are separate from each other in the above embodiments, a configuration may be adopted in which the mounting connector portion and the relay connector portion are formed as a single piece.

Although the heat of the IC is released to the shield layer via the outer conductor in the above embodiments, a configuration may be adopted in which heat is released without passing through the outer conductor.

Although the overhang portion protrudes rearward (in the direction in which the counterpart connector is fitted to the connector) and the sub-extension circuits, which are to come into contact with the overhang portion, extend in the front-rear direction (in the direction in which the connector and the counterpart connector are fitted to each other) in the above embodiments, the present disclosure is not limited to this configuration. For example, a configuration may be adopted in which the overhang portion protrudes in the width direction (in the direction orthogonal to the direction in which connector and the counterpart connector are fitted to each other) and the sub-extension circuits, which are to come into contact with the overhang portion, extend in the width direction.

1. A connector device comprising:
a circuit board provided with a main ground circuit; and
a connector mounted on the circuit board,
wherein the connector includes a sub-board, an IC mounted on the sub-board, and a heat transfer portion that transfers heat of the IC to the main ground circuit.

2. The connector device according to claim 1,
wherein the sub-board and the IC are disposed on one side of the circuit board in a board thickness direction,
the connector has a conductive cover member disposed to cover the sub-board and the IC from the one side of the circuit board in the board thickness direction, and
the heat transfer portion has a heat transfer portion for a cover that transfers heat of the IC to the cover member, and transfers the heat of the IC to the main ground circuit via the heat transfer portion for a cover and the cover member.

3. The connector device according to claim 2,
wherein the connector has a conductive attachment member mounted on the main ground circuit, and
the cover member is detachably attached to the attachment member.

4. The connector device according to claim 1,
wherein the circuit board and the sub-board are disposed such that their surfaces face each other,
the sub-board is provided with a sub-ground circuit disposed to face the main ground circuit provided on the circuit board,
the IC is connected to the sub-ground circuit,
a conductive member is provided between the sub-ground circuit and the main ground circuit, and
the conductive member is capable of electrical conduction between the sub-ground circuit and the main ground circuit.

5. The connector device according to claim 4,
wherein the connector has a mounting portion that is mounted on the circuit board and holds the sub-board, and
the conductive member biases the circuit board and the sub-board such that the circuit board and the sub-board are separated from each other in a direction in which their surfaces face each other.

6. The connector device according to claim 1,
wherein the connector has a conductive mounting cover member that covers the sub-board and the IC and is mounted on the main ground circuit, and
the heat transfer portion has a heat transfer portion for a mounting cover that transfers heat of the IC to the mounting cover member, and transfers the heat of the IC to the main ground circuit by the heat transfer portion for a mounting cover and the mounting cover member.

7. The connector device according to claim 1,
wherein the connector has an inner conductor and an outer conductor covering an outer periphery of the inner conductor,
the outer conductor is provided on the main ground circuit, and
the heat transfer portion has a heat transfer portion for an outer conductor that transfers heat of the IC to the outer conductor, and transfers the heat of the IC to the main ground circuit by the heat transfer portion for an outer conductor and the outer conductor.
